(19) United States
(12) Patent Application Publication
(10) Pub. No.: US 2008/0124887 A1
(43) Pub. Date: May 29, 2008

(54) METHOD FOR MANUFACTURING SEMICONDUCTOR DEVICE

(75) Inventor: Kenji Tanaka, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Chuo-ku (JP)

(21) Appl. No.: 11/945,762

(22) Filed: Nov. 27, 2007

(30) Foreign Application Priority Data
Nov. 29, 2006 (JP) 2006-322401

(51) Int. Cl. H01L 21/283

(52) U.S. Cl. 438/386; 257/E21.159

(57) ABSTRACT

A method for manufacturing semiconductor devices containing capacitors, the method includes: forming a second inter-layer insulating film over a first inter-layer insulating film; forming holes in the second inter-layer insulating film; forming a first electroconductive film covering the inner faces of the holes to form storage electrodes; forming thereafter a supporting film so as to fill the holes; exposing the outer side faces of the storage electrodes by removing at least part of the second inter-layer insulating film; exposing thereafter the inner side faces of the storage electrodes by removing the supporting films in the holes; forming a dielectric film covering the inner side faces and the outer side faces of the storage electrodes; and forming a second electroconductive film over the dielectric film to form a counter electrode.

### BACKGROUND OF THE INVENTION

1. Field of the Invention

The present invention relates to a method for manufacturing semiconductor devices, and more particularly to a technique effectively applicable to manufacturing methods for semiconductor devices having DRAM (Dynamic Random Access Memory) type memory elements.

2. Description of the Related Art

In a DRAM, a memory cell is composed of one transistor and one capacitor, and the memory cell can be operated as a memory element by utilizing the presence or absence of an electric charge held by the capacitor.

The miniaturization of semiconductor devices in recent years has obliged capacitors also to be miniaturized; the miniaturization of capacitors leads to a decrease in the charge storage capacity (Cs) of capacitors and consequently a significant drop in the reliability of DRAMs.

For this reason, many contrivances have been made to secure the charge storage capacity of capacitors even if the DRAM is miniaturized. One of these contrivances is a method which uses a new material having a high dielectric constant for the insulating film of the capacitor. However, application of a new material different from the conventional one into the semiconductor manufacturing process is feared to give rise to a new problem such as contamination. On the other hand, another way by which the problem of contamination is bypassed and a sufficient charge storage capacity is secured for the capacitor is to increase the surface area of the storage electrodes.

Japanese Patent Application Laid-Open No. 2000-196038 describes a method of forming a capacitor having storage electrodes of a crown-shaped structure. Its outline will be described below.

At the beginning, deep holes are formed in a thick insulating film. A storage electrode material is formed all over the surface including the insides of the deep holes. After that, a sacrificial material is so formed as to fill the space in the deep holes. The storage electrode material and the sacrificial material formed in the surface area elsewhere than the deep holes are removed to leave a state in which only the insides of the deep holes are filled with the storage electrode material and the sacrificial material. After that, wet etching is conducted to remove the thick insulating film positioned around the storage electrode. At this step, the storage electrode material and the sacrificial material remain unetched. After that, the sacrificial material in the deep hole is selectively removed relative to the storage electrode material to form storage electrodes of crown-shaped structure. In this case, an electroconductive material is used as the sacrificial material.

However, this example of the related art involves the following problem.

This problem lies in the removal of the electroconductive material and the thick insulating film, which are positioned in and out of the storage electrodes respectively, by wet etching in forming the storage electrodes of crown-shaped structure. More specifically, the thick insulating film is etched with hydrofluoric acid, and the electroconductive material, depending on what it is, is etched with heated sulfuric acid or hydrofluoric acid. Before the wet etching, there is no fear for the storage electrodes to fall down because they are supported by the thick insulating film around or the electroconductive material inside. However, the wet etching extinguishes those supports and exposes the storage electrodes which are poor in mechanical strength. As a result, the storage electrodes are causes to fall down by the surface tension of the solution when they are lifted from the solution, and the capacitor can no longer be formed.

### SUMMARY OF THE INVENTION

An object of the present invention is to provide a method for manufacturing semiconductor devices comprising a minute capacitor structure having large capacity.

According to one aspect of the invention, there is provided a method for manufacturing semiconductor devices comprising capacitors, the method comprising:

forming a second inter-layer insulating film over a first inter-layer insulating film;

forming holes in the second inter-layer insulating film;

forming a first electroconductive film covering the inner faces of the holes to form storage electrodes;

forming thereafter a supporting film so as to fill the holes;

exposing the outer side faces of the storage electrodes by removing at least part of the second inter-layer insulating film;

exposing thereafter the inner side faces of the storage electrodes by removing the supporting film in the holes;

forming a dielectric film covering the inner side faces and the outer side faces of the storage electrodes; and

forming a second electroconductive film over the dielectric film to form a counter electrode.

In the first aspect referred to above, removing of the second inter-layer insulating film can be accomplished by wet etching, and removing of the supporting film can be accomplished by dry etching.

In the first aspect referred to above, an amorphous carbon film can be formed as the supporting film.

According to another aspect of the invention, there is provided a method for manufacturing semiconductor devices comprising capacitors, the method comprising:

forming conductor plugs in a first inter-layer insulating film;

forming a second inter-layer insulating film over the conductor plugs and the first inter-layer insulating film;

forming holes in the second inter-layer insulating film and exposing the surfaces of the conductor plugs in these holes;

forming a first electroconductive film all over;

etching back the first electroconductive film to form storage electrodes made up of the first electroconductive film over the inner faces of the holes;

forming thereafter an amorphous carbon film so as to fill the holes;

exposing the surface of the second inter-layer insulating film by removing the amorphous carbon films formed outside the holes;

exposing the outer side faces of the storage electrodes by removing at least part of the second inter-layer insulating film;

exposing thereafter the inner side faces of the storage electrodes by removing the amorphous carbon film in the holes;

forming a dielectric film covering the inner side faces and the outer side faces of the storage electrodes; and

forming a second electroconductive film over the dielectric films to form a counter electrode.

According to another aspect of the invention, there is provided a method for manufacturing semiconductor devices comprising capacitors, the method comprising:

forming conductor plugs in a first inter-layer insulating film;

forming a second inter-layer insulating film over the conductor plugs and the first inter-layer insulating film;

forming holes in the second inter-layer insulating film and exposing the surfaces of the conductor plugs in these holes;

forming a first electroconductive film all over;

forming an amorphous carbon film over the first electroconductive film so as to fill the holes;

exposing the surface of the first electroconductive film over the second inter-layer insulating film by removing the amorphous carbon film formed outside the holes;

exposing the surface of the second inter-layer insulating film by removing the exposed part of the first electroconductive film to form storage electrodes made up of the first electroconductive film over the inner faces of the holes;

exposing the outer side faces of the storage electrodes by removing at least part of the second inter-layer insulating film;

exposing thereafter the inner side faces of the storage electrodes by removing the amorphous carbon film in the holes;

forming a dielectric film covering the inner side faces and the outer side faces of the storage electrodes; and

forming a second electroconductive film over the dielectric film to form a counter electrode.

According to any of the aspects described above, removing of the second inter-layer insulating film can be accomplished by wet etching.

According to any of the aspects described above, removing of the amorphous carbon film can be accomplished by dry etching.

According to any of the aspects described above, removing of the amorphous carbon film can be accomplished with gas plasma using a gas selected from the group consisting of oxygen, hydrogen and ammonia.

According to any of the aspects described above, the second inter-layer insulating film may comprise a laminated structure of a silicon nitride film on the lower layer side and a silicon oxide film of the upper layer side.

According to any of the aspects described above, the second inter-layer insulating film may comprise a laminated structure of a first silicon nitride film, a first silicon oxide film formed over the first silicon nitride film, a second silicon nitride film formed over the first silicon oxide film, and a second silicon oxide film formed over the second silicon nitride film.

The present can provide a method for manufacturing semiconductor devices comprising a minute capacitor structure having large capacity.

### BRIEF DESCRIPTION OF THE DRAWINGS

FIG. 1 shows a section of a step for describing a first exemplary embodiment of the semiconductor device manufacturing method according to the invention.

FIG. 2 shows a section of a step for describing the first exemplary embodiment of the semiconductor device manufacturing method according to the invention following FIG. 1.

FIG. 3 shows a section of a step for describing the first exemplary embodiment of the semiconductor device manufacturing method according to the invention following FIG. 2.

FIG. 4 shows a section of a step for describing the first exemplary embodiment of the semiconductor device manufacturing method according to the invention following FIG. 3.

FIG. 5 shows a section of a step for describing the first exemplary embodiment of the semiconductor device manufacturing method according to the invention following FIG. 4.

FIG. 6 shows a section of a step for describing the first exemplary embodiment of the semiconductor device manufacturing method according to the invention following FIG. 5.

FIG. 7 shows a section of a step for describing the first exemplary embodiment of the semiconductor device manufacturing method according to the invention following FIG. 6.

FIG. 8 shows a section of a step for describing the first exemplary embodiment of the semiconductor device manufacturing method according to the invention following FIG. 7.

FIG. 9 shows a section of a step for describing the first exemplary embodiment of the semiconductor device manufacturing method according to the invention following FIG. 8.

FIG. 10 shows a section of a step for describing the first exemplary embodiment of the semiconductor device manufacturing method according to the invention following FIG. 9.

FIG. 11 shows a section of a step for describing a second exemplary embodiment of the semiconductor device manufacturing method according to the invention.

FIG. 12 shows a section of a step for describing the second exemplary embodiment of the semiconductor device manufacturing method according to the invention following FIG. 11.

FIG. 13 shows a section of a step for describing another exemplary embodiment of the semiconductor device manufacturing method according to the invention.

### DETAILED DESCRIPTION OF THE EXEMPLARY EMBODIMENTS

A semiconductor device manufacturing method in one exemplary embodiment of the present invention comprises:

(1) a step of forming, after forming a conductor plug in a first inter-layer insulating film, a second inter-layer insulating film over the conductor plug and the first inter-layer insulating film;

(2) a step of forming a through hole in a prescribed area of the second inter-layer insulating film and exposing the top surface of the conductor plug in this through hole;

(3) a step of filling, after forming storage electrodes over the inner surface of the through hole, the hole with amorphous carbon;

(4) a step of exposing, after exposing the outer side faces of the storage electrodes by removing at least part of the second inter-layer insulating film, the inner side faces of the storage electrodes by removing the amorphous carbon; and

(5) a step of forming, after forming a dielectric film covering the inner side faces and the outer side faces of the storage electrodes, a counter electrode over the dielectric film.

The capacitor forming steps according to the invention are applicable to, for instance, a DRAM manufacturing method, and enables DRAMs to be formed by following the usually practice manufacturing process except the capacitor.

At these capacitor forming steps, if the thick inter-layer insulating film around the storage electrodes is to be removed by wet etching, the inside of the cylindrical storage electrodes is not hollow but filled with amorphous carbon when they are dried after this wet etching. Therefore, even if surface tension due to the drying of the etching solution works between the storage electrodes, they are prevented from falling down, supported by the amorphous carbon that fills them. Furthermore, as the amorphous carbon that fills them can be removed by dry etching (plasma etching), the falling of the storage electrodes, which would otherwise pose a problem in the execution of the drying after the wet etching due to the surface tension, can be avoided.

Incidentally, the “cylindrical” shape of the storage electrodes means a hollow cylindrical shape which is open at the upper end and has a bottom at the lower end.

The method for manufacturing semiconductor devices according to the invention will be described below with reference to exemplary embodiments thereof.

### Exemplary Embodiment 1

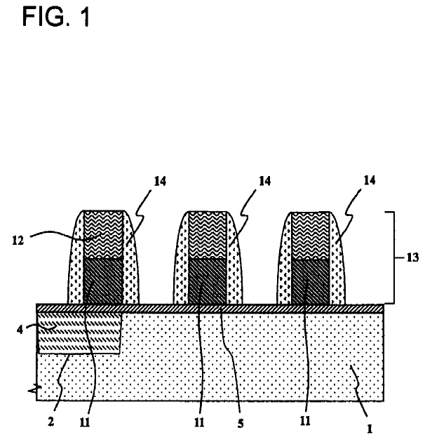

A first exemplary embodiment of the invention will be described below with reference to a series of sectional views of process steps designated as FIG. 1 through FIG. 10.

First, the structure shown in FIG. 1 was formed in the following manner. First, a silicon oxide film was buried into an element isolation trench 2 formed in a prescribed area of the surface of a semiconductor substrate 1 to form an element isolation area 4. After that, a gate oxide film 5 was formed over the surface of the semiconductor substrate 1 by thermal oxidation, and a polycrystalline silicon film 11 and a silicon nitride film 12 are formed by CVD (chemical vapor deposition). Next, the silicon nitride film 12 and the polycrystalline silicon film 11 were patterned by photolithography and dry etching to form a gate electrode 13, which would serve as word wiring. After that, a silicon nitride film was stacked all over, and etched back for form a side wall 14 made up of a silicon nitride film. After this, the source and drain of a MOS transistor (not shown in the drawing) were formed in a prescribed area of the semiconductor substrate 1 by ion implantation.

Before forming the side wall 14, the LDD area of the MOS transistor may be formed in a prescribed area of the semiconductor substrate 1, as required, by using ion implantation.

Incidentally, as the conductor layer of the gate electrode 13, what is formed by stacking a metal silicide layer or a metal layer over a polycrystalline silicon film can be used as well instead of using the polycrystalline silicon film 11 as a mono-layer. The polycrystalline silicon film here is so formed as to contain phosphorus as an impurity at the stage of film formation, and this is true of any polycrystalline silicon film in the following description.

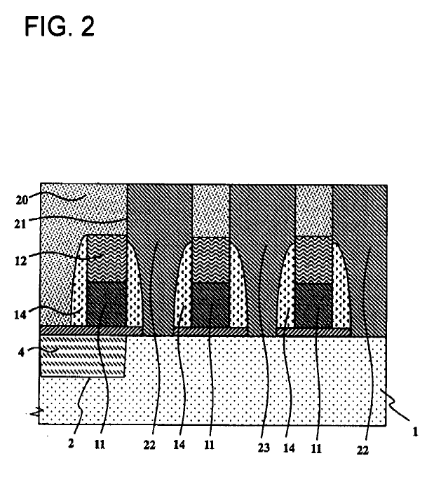

Next, the structure shown in FIG. 2 was formed in the following manner. First, an inter-layer insulating film 20 made up of a silicon oxide film was stacked all over by CVD, and its surface was flattened by CMP (chemical mechanical polishing). After that, contact holes 21 were formed by photolithography and dry etching in the inter-layer insulating film 20. Then, a polycrystalline silicon film was so stacked by CVD as to fill the contact holes 21, and the polycrystalline silicon film formed over the inter-layer insulating film 20 was removed by CMP to form contact plugs 22 and 23 made up of polycrystalline silicon films.

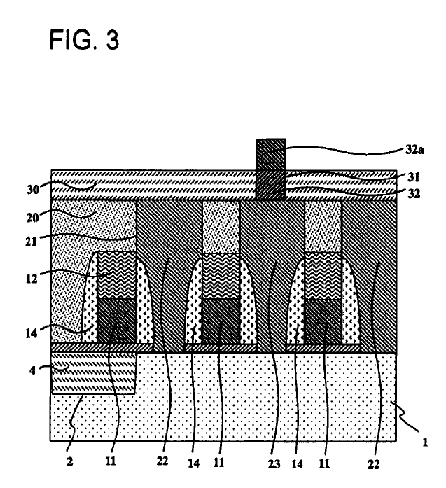

Then, the structure shown in FIG. 3 was formed in the following manner. After first forming a silicon oxide film 30 all over by CVD, a contact hole 31 was formed by photolithography and dry etching over the contact plug 23. Then, a bit wiring contact 32 made up of a laminated film of titanium silicide, titanium nitride and tungsten was formed. Further a laminated film of tungsten nitride and tungsten was stacked all over by sputtering and patterned by photolithography and dry etching to form bit wiring 32a.

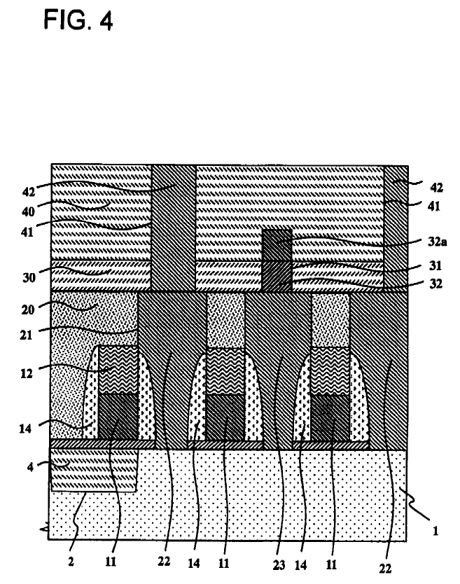

Next, the structure shown in FIG. 4 was formed in the following manner. First, a first inter-layer insulating film 40 made up of a silicon oxide film was stacked all over by CVD. Then, contact holes 41 penetrating the silicon oxide film 30 and the first inter-layer insulating film 40 were formed by photolithography and dry etching over the contact plugs 22, followed by the formation of conductor plugs 42 made up of polycrystalline silicon films.

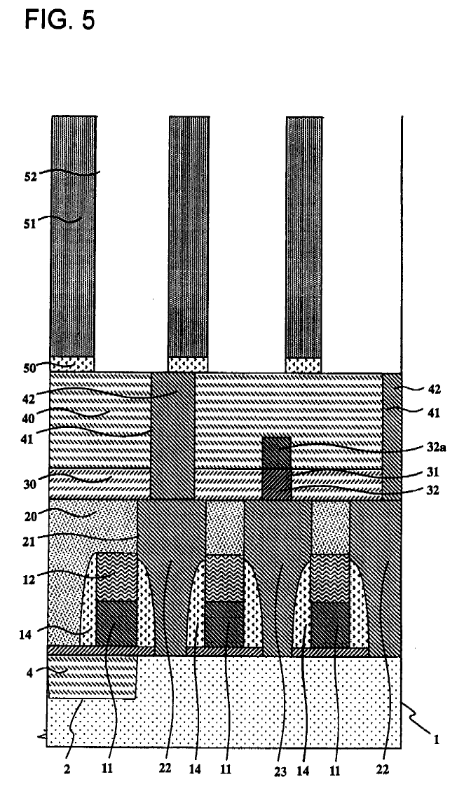

Next, the structure shown in FIG. 5 was formed in the following manner. First, a second inter-layer insulating film made up of a laminated film of a silicon nitride film 50 of 50 nm in thickness and a silicon oxide film 51 of 2500 nm in thickness was stacked by CVD. Then, deep holes 52 were so formed in a second inter-layer insulating film by photolithography and dry etching as to expose the surfaces of the conductor plugs 42. The silicon nitride film 50 was formed by thermal CVD using dichlorosilane (SiH₂Cl₂) and ammonia (NH₃) as reaction gases. The silicon oxide film 51 was formed by plasma CVD using tetraethoxysilane (Si(OC₂H₅)₄) and oxygen as reaction gases. The deep holes 52 were formed by dry etching using plasma containing fluorine. Though not shown in the drawing, as the silicon oxide film 51 is thick, the etching mask resistance of the photoresist formed by photolithography is sometimes insufficient. In this case, a hard mask of a polycrystalline silicon film or the like can be used.

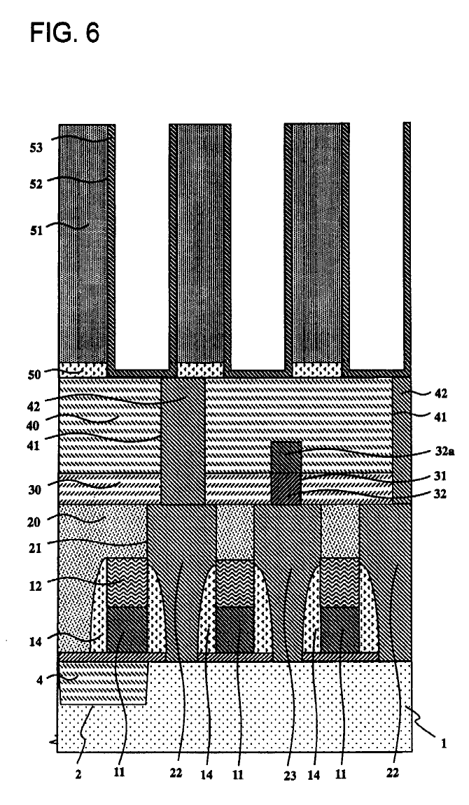

Next, the structure shown in FIG. 6 was formed in the following manner. First, a polycrystalline silicon film of 40 nm in thickness was stacked by CVD all over. Then, the polycrystalline silicon film formed over the surface elsewhere than the deep holes 52 was removed by CMP to leave the polycrystalline silicon film only over the inner faces of the deep holes 52, and storage electrodes 53 of the capacitor made up of this remaining polycrystalline silicon film were formed. At this stage, the storage electrodes 53 are connected to the conductor plugs 42.

Incidentally, the polycrystalline silicon film can be formed by subjecting a silicon film, which is amorphous at the stacked stage, to heat treatment to polycrystallize it. In this case, the silicon film was stacked by thermal CVD at a temperature of 520° C. using monosilane (SiH₄) and phosphine (PH₃) as raw material gases. The silicon film stacked under this temperature condition becomes an amorphous silicon film containing phosphorous. Since a silicon film in an amorphous state has no electroconductivity, it can be polycrystallized by heat treatment at a temperature of 700° C. The polycrystalline silicon film formed in this way has an advantage of extreme scarcity of unevenness of the surface.

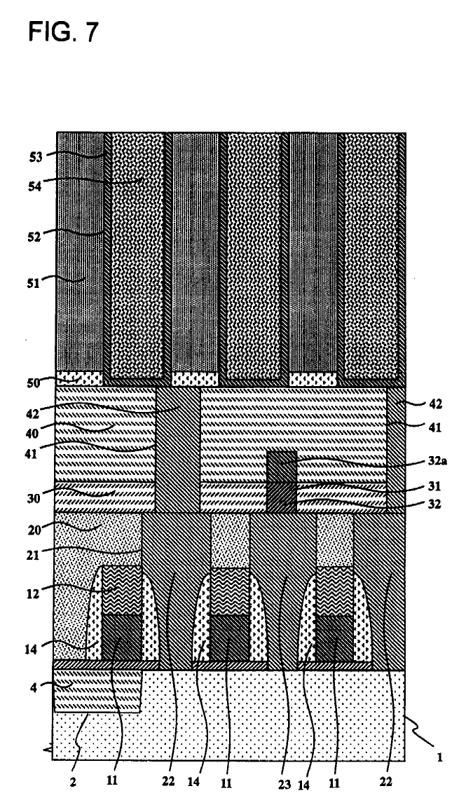

Next, the structure shown in FIG. 7 was formed in the following manner. After first stacking amorphous carbon all over, etching back was performed to leave amorphous carbon 54 only in the deep holes. Stacking of the amorphous carbon was accomplished by plasma CVD at a temperature of 550° C. using butane (C₄H₁₀) as raw material gas. Some other carbon hydride gas than butane can as well be used as raw material gas. For etching back, oxygen plasma etching was applied. Since no halogen gas such as fluorine or chlorine is contained, only the amorphous carbon can be removed without etching the silicon oxide film 51 or the storage electrodes 53 at all. The conditions of the plasma etching used for the etching back included the use of oxygen as etching gas, a pressure of 15 mTorr, a high frequency power of 300 W and a temperature of 20° C. Other than oxygen gas, a mixed gas of hydrogen and nitrogen or ammonia can be used as well. The set of etching conditions described here for etching the amorphous carbon is but one example, and the type of gas used, pressure, power, temperature and so forth can be altered as appropriate.

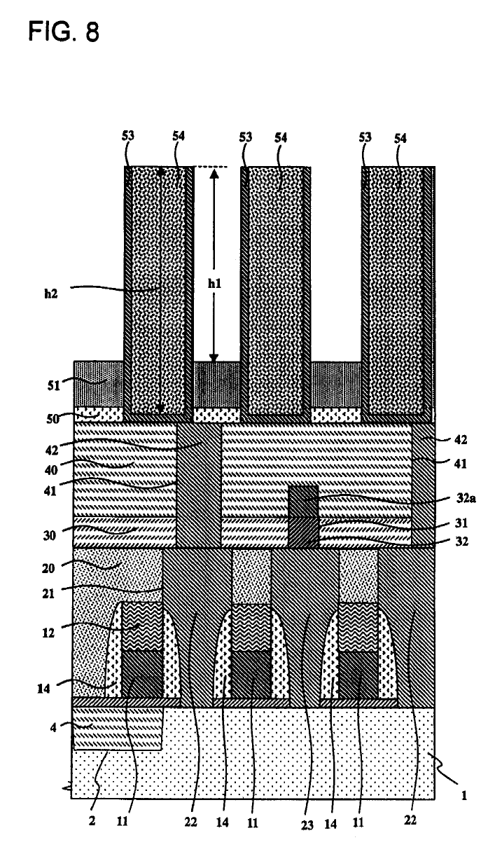

Next, as shown in FIG. 8, the silicon oxide film 51 making up the second inter-layer insulating film was etched back by wet etching. For the wet etching here, a solution containing hydrofluoric acid was used. The etching speed of the silicon oxide film 51 with a hydrofluoric acid-containing solution permits control of the etching depth according to the duration of etching. Here, the etching is so performed as to keep the etching depth h1 shown in the drawing shallower than the depth h2 of the deep holes composed of the storage electrodes 53 to keep the remaining film thickness of the silicon oxide film 51 at 500 nm.

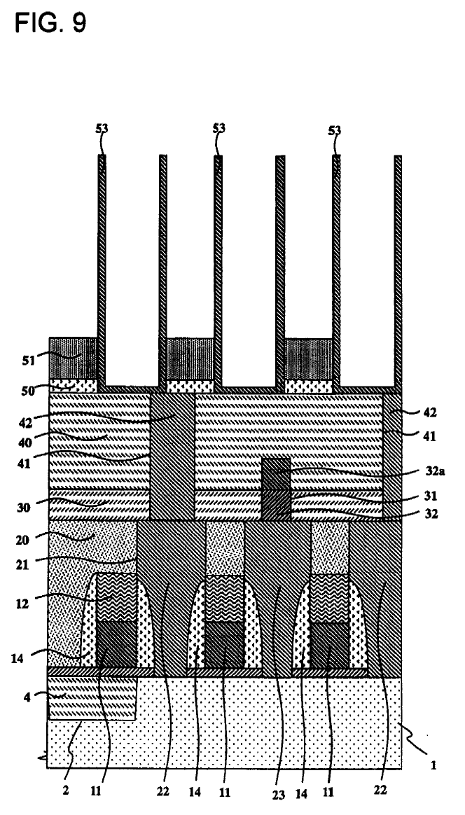

Next, as shown in FIG. 9, the amorphous carbon that has filled the insides of the deep holes was removed to form the storage electrodes 53 of crown-shaped structure made up of a polycrystalline silicon film. The removal of the amorphous carbon here was performed by aforementioned oxygen plasma etching. The conditions included the use of oxygen as etching gas, a pressure of 15 mTorr, a high frequency power of 300 W and a temperature of 20° C. Other than oxygen gas, a mixed gas of hydrogen and nitrogen or ammonia can be used as well. Other conditions including pressure, power and temperature can be altered as appropriate.

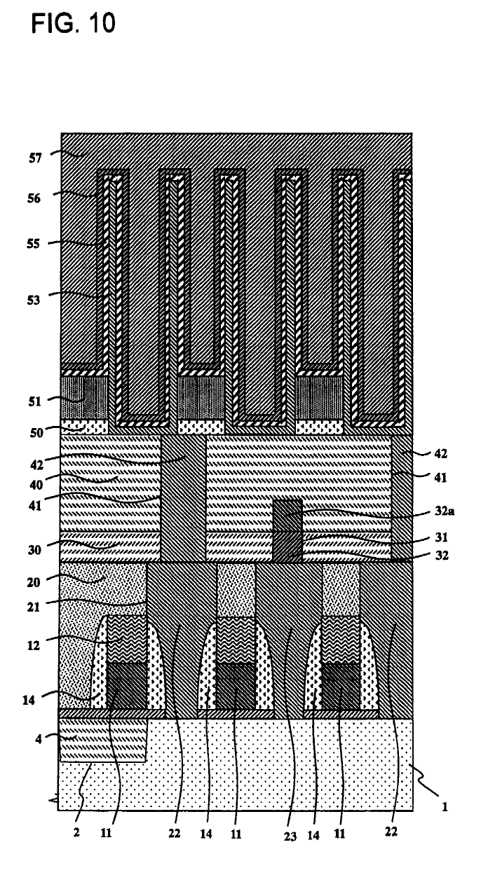

Next, as shown in FIG. 10, a dielectric 55 made up of a tantalum oxide film, and a upper electrode (a counter electrode) made up of titanium nitride 56 and tungsten 57 were formed to compose a capacitor. The tantalum oxide film which makes up the dielectric 55 here was formed by thermal CVD using pentaethoxytantalum (Ta(OC₂H₅)₅) and oxygen as raw material gases at a temperature of 530° C. and a pressure of 0.5 Torr. The film thickness was 8 nm. After the tantalum oxide film was formed, thermal treatment was applied in a nitrogen oxide (N₂O) gas ambience at a temperature of 750° C. for two minutes to reduce leak currents and enhance the dielectric constant. The titanium nitride 56 which was to constitute an upper electrode was formed by thermal CVD using titanium tetrachloride (TiCl₄) and ammonia (NH₃) as raw material gases at a temperature of 550° C. The film thickness was 40 nm. Further, the tungsten 57 was formed by sputtering, and the film thickness was 150 nm. The film thicknesses of the upper electrodes can be altered in various ways.

After the capacitor is composed, a semiconductor device can be fabricated through such known steps including the formation of inter-layer insulating films, that of through holes and that of wiring layers.

In this exemplary embodiment, when the thick second inter-layer insulating film around the storage electrodes 53 is etched by the wet etching, and the resulting structure is dried, the insides of the deep holes made up of the storage electrodes are filled with the amorphous carbon 54. Therefore, even if surface tension due to the drying of moisture works between the storage electrodes, the storage electrodes 53 are prevented from falling down supported by the amorphous carbon 54 that fills them. Further, as the amorphous carbon 54 that fills them can be removed by oxygen plasma etching which uses no solution, the falling of the storage electrodes 53 due to the surface tension on drying, which would otherwise pose a problem in the execution of wet etching, can be avoided.

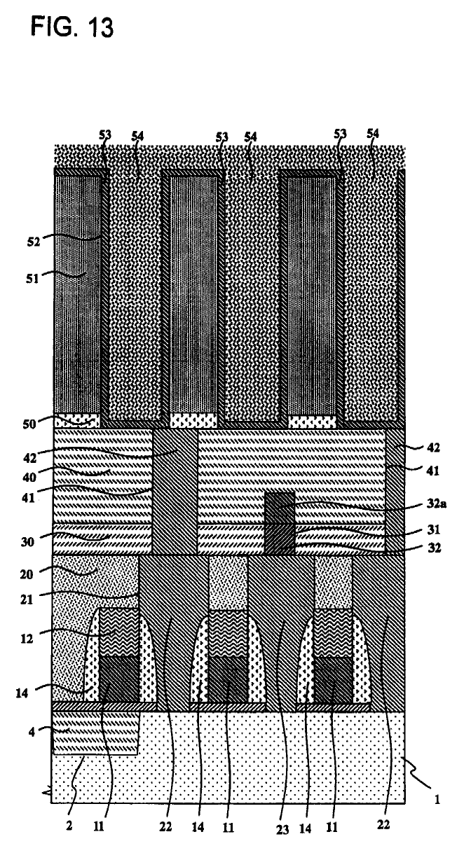

Incidentally in this exemplary embodiment, as shown in FIG. 6, after the storage electrodes 53 were formed over the inner faces of the deep holes 52, the amorphous carbon 54 was formed, the amorphous carbon over the second inter-layer insulating film was removed by oxygen plasma etching and, as shown in FIG. 7, the amorphous carbon was left only within the deep holes. Instead of this method, it is also possible to conduct a method comprising steps of achieving a state in which the polycrystalline silicon film and the amorphous carbon 54 constituting the storage electrodes 53 are stacked all over as shown in FIG. 13; removing the amorphous carbon 54 outside the deep holes by oxygen plasma etching; and removing the storage electrodes 53 outside the deep holes by dry etching.

This method enables the number of rounds of washing for removing the residuals of etching, which is usually performed after dry etching, to be reduced, and accordingly to reduce the number of process steps.

### Exemplary Embodiment 2

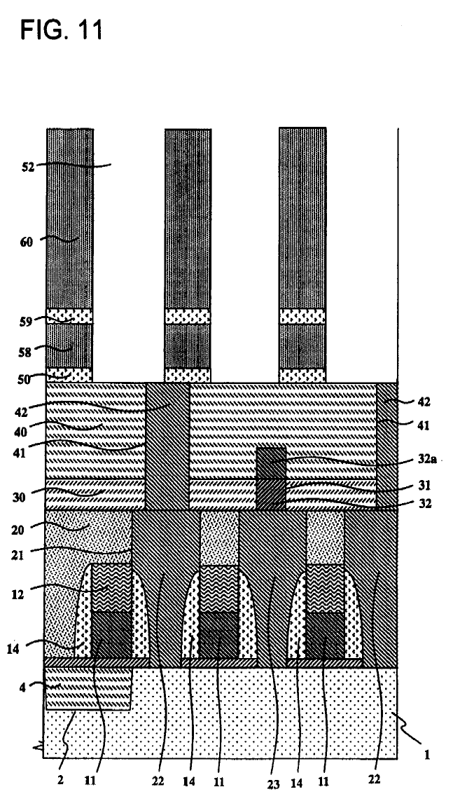

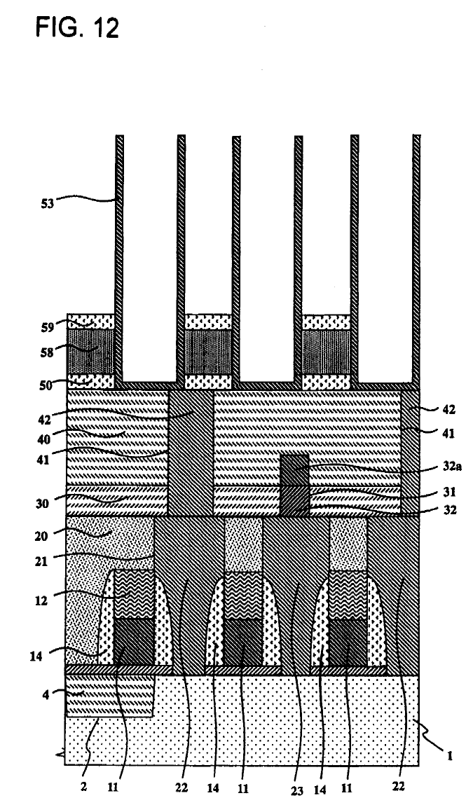

A second exemplary embodiment of the present invention will be described below with reference to sectional views of process steps designated as FIG. 11 and FIG. 12. Other steps than those described with reference to FIG. 11 and FIG. 12 are the same as in the foregoing Exemplary embodiment 1, and accordingly their description will be dispensed with.

First, the deep holes 52 were formed in the second inter-layer insulating film as shown in FIG. 11.

The difference from Exemplary embodiment 1 lies in that, while the second inter-layer insulating film was formed of a two-layered film in Exemplary embodiment 1, in this exemplary embodiment the number of layers is further increased to make it a four-layered film. Thus in this exemplary embodiment, the second inter-layer insulating film is composed of a four-layered film comprising a silicon nitride film 50 of 50 nm in thickness, a silicon oxide film 58 of 500 nm in thickness, a silicon nitride film 59 of 50 nm in thickness and a silicon oxide film 60 of 2000 nm in thickness. The methods of forming the individual films are the same as those described with reference to Exemplary embodiment 1.

Next, the storage electrodes 53 of crown-shaped structure were formed as shown in FIG. 12 through the process steps described with reference to Exemplary embodiment 1.

In this exemplary embodiment, the second inter-layer insulating film is composed of a four-layered film comprising silicon oxide films which are rapidly etched with a hydrofluoric acid-containing solution and silicon nitride films which are slower to be etched. Therefore, wet etching can be stopped with the silicon nitride film 59 and only the silicon oxide film of 2000 nm in thickness can be removed.

This second exemplary embodiment, since the silicon nitride films 50 and 59 and silicon oxide film 58 are caused to remain therein, can reduce the unevenness of etching depth in wet etching and enhance the effect to prevent the storage electrodes 53 from falling down in addition to the benefit of the amorphous carbon in the first exemplary embodiment.

What is claimed is:

1. A method for manufacturing semiconductor devices comprising capacitors, the method comprising:
forming a second inter-layer insulating film over a first inter-layer insulating film;
forming holes in the second inter-layer insulating film;
forming a first electroconductive film covering the inner faces of the holes to form storage electrodes;
forming thereafter a supporting film so as to fill the holes;
exposing the outer side faces of the storage electrodes by removing at least part of the second inter-layer insulating film;
exposing thereafter the inner side faces of the storage electrodes by removing the supporting film in the holes;
forming a dielectric film covering the inner side faces and the outer side faces of the storage electrodes; and
forming a second electroconductive film over the dielectric film to form a counter electrode.

2. The method for manufacturing semiconductor devices according to claim 1, wherein removing of the second inter-layer insulating film is accomplished by wet etching, and removing of the supporting film is accomplished by dry etching.

3. The method for manufacturing semiconductor devices according to claim 1, wherein the supporting film is an amorphous carbon film.

4. A method for manufacturing semiconductor devices comprising capacitors, the method comprising:
forming conductor plugs in a first inter-layer insulating film;
forming a second inter-layer insulating film over the conductor plugs and the first inter-layer insulating film;
forming holes in the second inter-layer insulating film and exposing the surfaces of the conductor plugs in these holes;
forming a first electroconductive film all over;
etching back the first electroconductive film to form storage electrodes made up of the first electroconductive film over the inner faces of the holes;
forming thereafter an amorphous carbon film so as to fill the holes;
exposing the surface of the second inter-layer insulating film by removing the amorphous carbon film formed outside the holes;
exposing the outer side faces of the storage electrodes by removing at least part of the second inter-layer insulating film;
exposing thereafter the inner side faces of the storage electrodes by removing the amorphous carbon film in the holes;
forming a dielectric film covering the inner side faces and the outer side faces of the storage electrodes; and
forming a second electroconductive film over the dielectric films to form a counter electrode.

5. A method for manufacturing semiconductor devices comprising capacitors, the method comprising:
forming conductor plugs in a first inter-layer insulating film;
forming a second inter-layer insulating film over the conductor plugs and the first inter-layer insulating film;
forming holes in the second inter-layer insulating film and exposing the surfaces of the conductor plugs in these holes;
forming a first electroconductive film all over;
forming an amorphous carbon film over the first electroconductive film so as to fill the holes;
exposing the surface of the first electroconductive film over the second inter-layer insulating film by removing the amorphous carbon film formed outside the holes;
exposing the surface of the second inter-layer insulating film by removing the exposed part of the first electroconductive film to form storage electrodes made up of the first electroconductive film over the inner faces of the holes;
exposing the outer side faces of the storage electrodes by removing at least part of the second inter-layer insulating film;
exposing thereafter the inner side faces of the storage electrodes by removing the amorphous carbon film in the holes;
forming a dielectric film covering the inner side faces and the outer side faces of the storage electrodes; and
forming a second electroconductive film over the dielectric film to form a counter electrode.

6. The method for manufacturing semiconductor devices according to claim 4, wherein removing of the second inter-layer insulating film is accomplished by wet etching.

7. The method for manufacturing semiconductor devices according to claim 5, wherein removing of the second inter-layer insulating film is accomplished by wet etching.

8. The method for manufacturing semiconductor devices according to claim 4, wherein removing of the amorphous carbon film is accomplished by dry etching.

9. The method for manufacturing semiconductor devices according to claim 5, wherein removing of the amorphous carbon film is accomplished by dry etching.

10. The method for manufacturing semiconductor devices according to claim 4, wherein removing of the amorphous carbon film is accomplished with gas plasma using a gas selected from the group consisting of oxygen, hydrogen and ammonia.

11. The method for manufacturing semiconductor devices according to claim 5, wherein removing of the amorphous carbon film is accomplished with gas plasma using a gas selected from the group consisting of oxygen, hydrogen and ammonia.

12. The method for manufacturing semiconductor devices according to claim 4, wherein the second inter-layer insulating film comprises a laminated structure of a silicon nitride film on the lower layer side and a silicon oxide film of the upper layer side.

13. The method for manufacturing semiconductor devices according to claim 5, wherein the second inter-layer insulating film comprises a laminated structure of a silicon nitride film on the lower layer side and a silicon oxide film of the upper layer side.

14. The method for manufacturing semiconductor devices according to claim 4, wherein the second inter-layer insulating film comprises a laminated structure of a first silicon nitride film, a first silicon oxide film formed over the first silicon nitride film, a second silicon nitride film formed over the first silicon oxide film, and a second silicon oxide film formed over the second silicon nitride film.

15. The method for manufacturing semiconductor devices according to claim 5, wherein the second inter-layer insulating film comprises a laminated structure of a first silicon nitride film, a first silicon oxide film formed over the first silicon nitride film, a second silicon nitride film formed over the first silicon oxide film, and a second silicon oxide film formed over the second silicon nitride film.
